(19) United States
(12) Patent Application Publication
(10) Pub. No.: US 2024/0379895 A1
(43) Pub. Date: Nov. 14, 2024

(54) SYSTEM FOR ELECTRICALLY CONTACTING WAFER SOLAR CELLS, IN-LINE PRODUCTION DEVICE, AND METHOD FOR PRODUCING A WAFER SOLAR CELL

(71) Applicant: HANWHA Q CELLS GMBH, Bitterfeld-Wolfen (DE)

(72) Inventors: Ansgar METTE, Bitterfeld-Wolfen (DE); Martin SCHAPER, Bitterfeld-Wolfen (DE); Stefan HÖRNLEIN, Bitterfeld-Wolfen (DE); Michael QUINQUE, Bitterfeld-Wolfen (DE); Tino WIECZOREK, Bitterfeld-Wolfen (DE)

(21) Appl. No.: 18/688,921

(22) PCT Filed: Sep. 8, 2022
(86) PCT No.: PCT/DE2022/100663

§ 371 Date: Apr. 16, 2024

(30) Foreign Application Priority Data
Sep. 8, 2021 (DE) 10 2021 123 280.5

(51) Int. Cl. H01L 31/18

(52) U.S. Cl. CPC H01L 31/1876

(57) ABSTRACT

A system for electrically contacting wafer solar cells with a front-face electrode, including: an upper contact device for electrically contacting the front-face electrode of the wafer solar cell, —a lower contact device for electrically contacting the rear-face electrode of the wafer solar cell, and an electric voltage source for applying a defined voltage to the wafer solar cell and regulating the flow of current between the upper and lower contact devices. The upper contact device and the lower contact device are designed to additionally mechanically convey the wafer solar cell along an in-line transport direction for an in-line production line for wafer solar cells while contacting the wafer solar cell.

### RELATED APPLICATIONS

The present application is a National Phase entry of PCT Application No. PCT/DE2022/100663, filed Sep. 8, 2022, which claims priority to German Patent Application No. 10 2021 123 280.5, filed Sep. 8, 2021, the disclosures of which are hereby incorporated by reference herein in their entirety.

### FIELD OF THE INVENTION

The invention relates to a system for electrically contacting wafer solar cells, to an in-line production device and to a method for producing a wafer solar cell. In particular, the invention relates to a system which is designed for electrically contacting wafer solar cells having a front-face electrode and having a rear-face electrode, to an in-line production device which comprises a system of this kind, and to a production method which produces a wafer solar cell using the system or the in-line production device.

### BACKGROUND OF THE INVENTION

A system of this kind is known from DE 10 2016 009 560 A1. The system has an upper contact device for electrically contacting the front-face electrode of the wafer solar cell, a lower contact device for electrically contacting the rear-face electrode of the wafer solar cell, and an electrical voltage source in order to apply a defined voltage to the wafer solar cell and to regulate the flow of current between the upper contact device and the lower contact device. This system is applied to a stationarily contacted wafer solar cell, wherein a single roller or a brush is guided along the stationary wafer solar cell in order to apply voltage to the wafer solar cell. Furthermore, a spot-type light source is guided over the front face of the wafer solar cell when the voltage is applied, as a result of which a light-induced flow of current is generated. This method is referred to as LECO (Laser Enhanced Cell Optimization) because, in particular, electrical contacting of the front-face electrode with the underlying semiconductor material of the wafer solar cell is improved in this way.

### SUMMARY

An object of the invention is to provide a system, an in-line production device and a production method which provide an improved ability to electrically contact wafer solar cells.

According to the invention, this object is achieved by a system having the features of patent claim 1, an in-line production device having the features of patent claim 11, and a production method having the features of patent claim 12. Advantageous modifications and developments are specified in the dependent claims.

According to the invention, it is provided that the upper contact device and the lower contact device are designed and configured to additionally mechanically convey the wafer solar cell along an in-line transportation direction for an in-line production line for wafer solar cells during the contacting operation.

The invention is based on the fundamental idea of conveying wafer solar cells having a front-face electrode and a rear-face electrode on either side by means of contact devices, the polarity of which is reversed by means of the electrical voltage source. The upper contact device and the lower contact device are designed to jointly convey wafer solar cells in a continuous process, the front face and the rear face of the wafer solar cells having metal contacts in the form of electrodes. The contact between the upper contact device and the lower contact device by way of the wafer solar cell therefore takes place while the wafer solar cell is moving, so that the wafer solar cell is electrically contacted by way of its front face and its rear face by the contact devices. The upper contact device and the lower contact device are integrated in the system in a stationary manner. The electrical voltage source is used to move the wafer solar cell to a predetermined state by semiconductor technology. The voltage source is preferably designed to apply voltage to the upper contact device and the lower contact device and furthermore to apply a defined voltage to the wafer solar cell contacting the contact devices. In particular, the flow of current between the upper contact device and the lower contact device and therefore the flow of current through the wafer solar cell can be regulated in this way.

The system can therefore be used for optimizing wafer solar cell contacts in the form of front- and rear-face electrodes and/or also for characterizing wafer solar cells. The system is preferably used for optimizing wafer solar cell contacts.

The front face of the wafer solar cell is a face of the wafer solar cell on which light, in particular sunlight, is incident when the wafer solar cell is used as intended, while the rear face represents a side that is averted from light during operation. The front-face electrode is preferably a screen-printed finger contact electrode.

The polarity of the electrical voltage source is preferably adjustable in a range of 0 V to 50 V, preferably in a range of 10 V to 25 V.

A contact pressure of the contact devices onto the wafer solar cell is preferably selected in such a way that good electrical contacting of the wafer solar cell is performed, but there is no mechanical damage to the sensitive semiconductor wafer material.

In an advantageous embodiment, the lower contact device moves equally as quickly as the wafer solar cell along the in-line transportation direction and is designed as a conveyor belt device.

The conveyor belt device can have one or more conveyor belts. The conveyor belt device preferably has a vacuum conveyor belt device or a vacuum belt transportation device. As an alternative, the lower contact device can have one or more chucks.

The upper contact device preferably has at least one upper contact element as viewed along the in-line transportation direction and perpendicularly to the in-line transportation direction, the upper contact element being designed as a cylinder or as a roller with a contact periphery, wherein the contact periphery rolls on the front-face electrode of the wafer solar cell as quickly as the wafer solar cell moves along the in-line transportation direction. As a result, a device can be arranged between the upper contact elements, said device being designed to interact with the front side of the conveyed wafer solar cell.

In a preferred embodiment, the upper contact device has at least one upper contact element as viewed along the in-line transportation direction and perpendicularly to the in-line transportation direction, the upper contact element being designed as a cylinder or as a roller with a contact periphery, wherein the contact periphery rolls on the front-face electrode of the wafer solar cell as quickly as the wafer solar cell moves along the in-line transportation direction, and the lower contact device has at least one lower contact element as viewed along the in-line transportation direction and perpendicularly to the in-line transportation direction, the lower contact element being designed as a cylinder or as a roller with a contact periphery, wherein the contact periphery rolls on the rear-face electrode of the wafer solar cell as quickly as the wafer solar cell moves along the in-line transportation direction. Therefore, in this embodiment, both the at least one upper and the at least one lower contact element are each designed as a cylinder or roller. The upper and/or lower contact elements can be manufactured, for example, from metal, such as steel for example, and/or from electrically conductive polymers, preferably soft polymers.

In a preferred embodiment, the upper contact element or the upper contact elements and the lower contact element or the lower contact elements are arranged opposite each other in pairs as viewed perpendicularly to the in-line transportation direction.

The upper contact element and the opposite lower contact element, by way of their respective contact periphery, are arranged with a contact spacing from each other that is somewhat less than or equal to a thickness of the wafer solar cell. The upper and the lower contact element are mechanically supported in such a way that, when the wafer solar cell rolls in between the contact elements, the spacing between the contact elements is matched to the thickness of the wafer solar cell. As an alternative, the material of the contact elements that is used can have a degree of elasticity that is sufficient to ensure electrical contacting of the front-face electrode and the rear-face electrode when the wafer solar cell rolls in.

In the absence of a wafer solar cell, mutually opposite contact elements are preferably physically spaced apart from each other by a gap, so as to ensure that the upper contact element and the lower contact element are not electrically contacted by mechanical contact. This prevents a short circuit between the contact elements of opposing polarity. The gap between the upper contact element and the opposite lower contact element can be predetermined and/or adjustable depending on the thickness of the wafer solar cell to be conveyed. For example, it is also possible to design the upper contact element such that it can be mechanically lowered, so that it is lowered, in order to contact the wafer solar cell, as soon as the wafer solar cell is located beneath it. Damage to the edge of the wafer solar cell can be avoided in this way. As an alternative, a variable pressure for the upper contact element and/or the lower contact element can also be realized, for example by means of springs, weights, flexible layers, servos etc.

The contact spacing between the upper contact element and the opposite lower contact element is preferably realized by an electrically insulating spacing portion which is arranged on the respective contact element axially adjacent to the contact periphery of the upper contact element and/or axially adjacent to the lower contact element as viewed along the rotation axis of the respective contact elements. The electrically insulating spacing portion is manufactured, for example, from plastic or rubber. At least the surface of the upper or the lower contact element that is in contact with the wafer solar cell to be conveyed during operation is electrically conductive. The upper or lower contact element can be manufactured from metal and provided with plastic or rubber in the spacing portion. As an alternative, the upper or lower contact element can be produced from plastic or rubber and be coated with metal in the spacing portion.

In a preferred embodiment, the lower contact device has a lower conveying element in the form of a roller or a cylinder with an electrically insulating contact periphery opposite the upper contact element as viewed perpendicularly to the in-line transportation direction and the upper contact device has an upper conveying element in the form of a roller or a cylinder with an electrically insulating contact periphery opposite the lower contact element. This arrangement can ensure that no short circuit is produced between the paired contact elements during operation of the system. The electrical insulation can be achieved, for example, by way of the conveying element being manufactured from plastic or rubber.

If the upper contact device has a plurality of upper contact elements and/or conveying elements, the upper contact elements are preferably arranged next to one another along the in-line transportation direction. The same applies for the lower contact device and its lower contact elements and/or conveying elements. The upper contact elements and upper conveying elements are preferably arranged next to one another along the in-line transportation direction and the lower contact elements and lower conveying elements are preferably arranged next to one another along the in-line transportation direction offset thereto, so that they are arranged opposite each other in pairs. For example, the upper contact device has four upper conveying elements, two upper contact elements with a positive polarity and four upper conveying elements next to each other in the specified order, whereas the lower contact device has three lower conveying elements, one lower contact element with a negative polarity, two lower conveying elements, one lower contact element with a negative polarity and three lower conveying elements next to each other in the specified order. The conveying elements arranged in pairs are used to feed the wafer solar cell into and out of the region with the upper and lower contact elements in which the wafer solar cell is electrically contacted.

The upper contact device and the lower contact device preferably have at least two upper contact elements and at least two lower contact elements as viewed along the in-line transportation direction, the spacing between the two upper contact elements and between the two lower contact elements along the in-line transportation direction being smaller than the dimensions of the wafer solar cell to be processed. This ensures that the wafer solar cell is conveyed by means of both contact element pairs.

In a preferred embodiment, the system has a laser device which moves or projects a laser beam over a front face of the wafer solar cell transversely to the in-line transportation direction. Once a voltage has been applied to the upper contact device and to the lower contact device by means of the electrical voltage source, the charge carrier pairs induced by the laser light can be removed by suction. Owing to the locally high current density at the metal electrode, the electrical contact between the semiconductor material and the metal electrodes is improved.

The laser device is preferably arranged and designed in such a way as to integrate the process of laser machining between the upper contact elements and possibly conveying elements onto the front face. The laser device is preferably designed as a scanning laser, which can generate a high photocurrent. The movement or projection of the laser device is preferably executed in such a way that the photocurrent generated by means of the laser device flows away via the front-face electrode and the at least one upper contact element and the at least one lower contact element, and in so doing improves contacting of the upper contact element and lower contact element. The laser device is preferably moved perpendicularly to the in-line transportation direction, preferably parallel to a longitudinal extent of the upper contact element in the form of the cylinder or roller. A laser scanning rate is preferably automatically adapted to a transportation speed at which the wafer solar cell is conveyed into the in-line transportation direction

An upper contact element and a lower contact element are preferably each arranged in pairs upstream and downstream of the laser device as viewed in the in-line transportation direction such that, as the wafer solar cell passes through, at least one of the contact element pairs always contacts the wafer solar cell and thus discharges the laser current. These electrically conductive contact elements arranged in pairs, when the wafer solar cell is contacted by said contact elements, can be used as detectors for the laser device and any laser protection devices that may be provided. In the case of a conveyed wafer solar cell, a voltage measurement can identify whether the wafer solar cell is electrically contacted on the front face and the rear face, and therefore the position can be exactly determined. In particular, the position of the wafer solar cells can be determined on the basis of changes in potential of the upper and lower contact elements. The system preferably contains a voltage measuring device, which is designed to measure the potential between the contact elements of opposite polarity. As an alternative, the system can preferably have a detection device, which is designed to identify a position of the wafer solar cell by means of optical identification, for example a photoelectric barrier. The upper and the lower contact elements can therefore be used as shutter signal transmitters for a laser protection device.

The invention also relates to an in-line production device for a wafer solar cell comprising a system as claimed in one or more of the embodiments described above. The in-line production device has, in addition to the system described above, a plurality of further stations for producing the wafer solar cell starting from a semiconductor wafer or a semifinished wafer solar cell product.

The invention furthermore relates to a method for producing a wafer solar cell using a system according to one or more of the embodiments described above or using the in-line production device according to one or more of the embodiments described above, wherein an in-line transportation speed of the wafer solar cells along the in-line transportation direction of 0.1 to 60 m/min, preferably of 3 to 20 m/min, and particularly preferably of 6 to 20 m/min, is realized.

### BRIEF DESCRIPTION OF THE DRAWINGS

The invention will be explained below on the basis of exemplary embodiments with reference to the figures, in which diagrammatically and in a manner not true to scale:

FIG. 1 shows a diagrammatic cross-sectional view of a system according to a first embodiment during operation;

FIG. 2 shows a perspective diagrammatic view of a system according to a second embodiment during operation;

FIGS. 3 and 4 both show a diagrammatic cross-sectional view of a system according to a third embodiment during operation;

FIGS. 5 and 6 both show a diagrammatic side view of a pair of cylinder contact elements 10, 20 from a system according to a fourth embodiment during operation; and

FIG. 7 shows a diagrammatic cross-sectional view of a system according to a fifth embodiment during operation.

### DETAILED DESCRIPTION

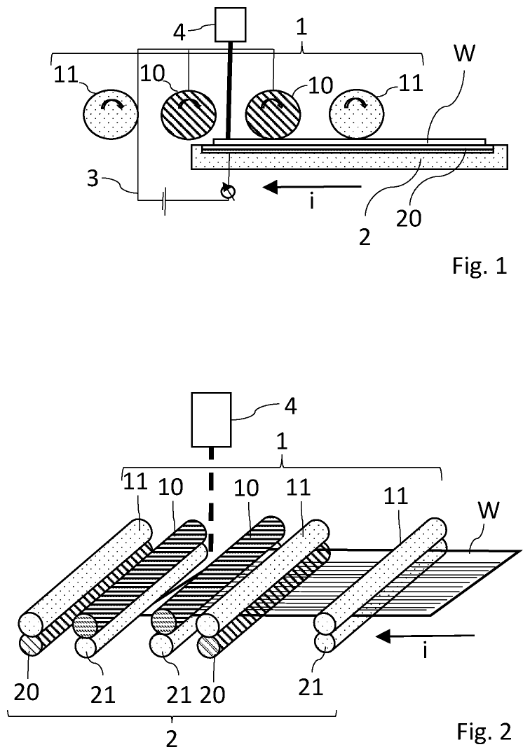

FIG. 1 shows a diagrammatic cross-sectional view, which is not true to scale, of a system according to a first embodiment during operation. The system is designed for electrically contacting wafer solar cells W having a front-face electrode (not shown) and having a rear-face electrode (not shown). The system has an upper contact device 1 for electrically contacting the front-face electrode of the wafer solar cell W, a lower contact device 2 for electrically contacting the rear-face electrode of the wafer solar cell W, and an electrical voltage source in order to apply a defined voltage to the wafer solar cell and to regulate the flow of current between the upper contact device 1 and the lower contact device 2. The upper contact device 1 and the lower contact device 2 are designed and configured to mechanically convey the wafer solar cell W along an in-line transportation direction i as a production section in an in-line production line (not shown) for wafer solar cells W during the contacting operation.

The lower contact device 2 moves equally as quickly as the wafer solar cell W along the in-line transportation direction i. The lower contact device is designed as a conveyor belt device which has a lower contact element 20. The upper contact device 1 has a plurality of upper contact elements 10 as viewed along the in-line transportation direction i and perpendicularly to the in-line transportation direction i, the upper contact elements each being designed as a cylinder or as a roller with a contact periphery, wherein the contact periphery rolls on the front-face electrode of the wafer solar cell W as quickly as the wafer solar cell W moves along the in-line transportation direction i. The lower contact element 20 and the upper contact elements 10 have an opposite polarity during operation. The upper contact device 1 also has a plurality of upper conveying elements 11, each in the form of a roller or a cylinder with an electrically insulating contact periphery, opposite the lower contact element 20. The upper contact elements 10 and upper conveying elements 11 each rotate in a clockwise direction of rotation indicated by an arrow. The lower contact device 2 has an electrically insulated region into which the lower contact element 20 is integrated.

The system furthermore has a laser device 4 which moves or projects a laser beam over a front face of the wafer solar cell W transversely to the in-line transportation direction i.

The system also has an electrical feed device 3 with a voltage source, forming an electrical circuit together with the upper contact elements 10 and the lower contact element 20. In a defined time window after the electrical circuit between the first upper contact element 10 and the lower contact element 20 as viewed in the in-line transportation direction i has been closed, the laser device 4 can be actuated such that it interacts with the wafer solar cell conveyed beneath it. The defined time window can be calculated using the conveying speed and the dimensions of the wafer solar cell along the in-line transportation direction i.

FIG. 2 shows a perspective diagrammatic view of a system according to a second embodiment during operation. This system is designed to electrically contact wafer solar cells W having a front-face electrode (here indicated in the form of the large number of horizontal lines) and having a rear-face electrode (not shown). The system has an upper contact device 1 for electrically contacting the front-face electrode of the wafer solar cell W, a lower contact device 2 for electrically contacting the rear face electrode of the wafer solar cell W, and an electrical voltage source (not shown here) in order to apply a defined voltage to the wafer solar cell and to regulate the flow of current between the upper contact device 1 and the lower contact device 2. The upper contact device 1 and the lower contact device 2 are designed and configured to mechanically convey the wafer solar cell W along an in-line transportation direction i for an in-line production line for wafer solar cells W during the contacting operation.

The upper contact device 1 has a plurality of upper contact elements 10 as viewed along the in-line transportation direction i and perpendicularly to the in-line transportation direction i, the upper contact elements each being designed as a cylinder or as a roller with a contact periphery, wherein the contact periphery rolls on the front-face electrode of the wafer solar cell W as quickly as the wafer solar cell W moves along the in-line transportation direction i. The lower contact device 2 likewise has a plurality of lower contact elements 20 as viewed along the in-line transportation direction i and perpendicularly to the in-line transportation direction i, the lower contact elements being designed as a cylinder or as a roller with a contact periphery, wherein the contact periphery rolls on the rear-face electrode of the wafer solar cell W as quickly as the wafer solar cell W moves along the in-line transportation direction i. The lower contact elements 20 and the upper contact elements 10 have an opposite polarity during operation. The upper contact device 1 has an upper conveying element 11 in the form of a roller or a cylinder with an electrically insulating contact periphery opposite each lower contact element 20, so that these upper conveying elements and lower conveying elements are arranged opposite each other in pairs as viewed perpendicularly to the in-line transportation direction i. The lower contact device 2 also has a lower conveying element 21 in the form of a roller or a cylinder with an electrically insulating contact periphery opposite each upper contact element 10, so that these lower conveying elements and upper contact elements are arranged opposite each other in pairs as viewed perpendicularly to the in-line transportation direction i. The upper contact device 1 and the lower contact device 2 each have a conveying element 11, 21 in each case in the form of a roller or a cylinder with an electrically insulating contact periphery, the conveying elements being arranged opposite each other in pairs as viewed perpendicularly to the in-line transportation direction i.

The system further has a laser device 4 which moves or projects a laser beam over a front face of the wafer solar cell W transversely to the in-line transportation direction i.

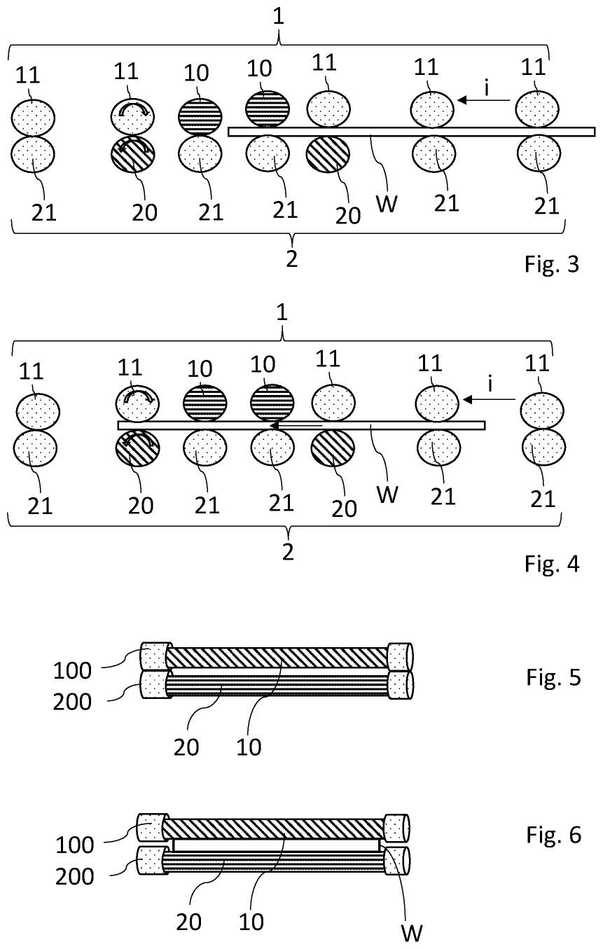

FIGS. 3 and 4 both show, diagrammatically and in a manner not true to scale, a cross-sectional view of a system according to a third embodiment during operation. The system shown in FIGS. 3 and 4 corresponds to the system shown in FIG. 2 with the difference that the number of conveying elements 11, 21 is different. The wafer solar cell W is moved in the in-line transportation direction i by means of the upper and lower contact elements 10, 20 and the conveying elements 11, 21. The pair of cylinder contact elements 20, 10 shown in this embodiment and the associated conveying elements 21, 11 rest mechanically on each other in the absence of a wafer solar cell. When a wafer solar cell is conveyed between the contact elements 20, 10 and the associated conveying elements 21, 11, the spacing between the associated rotation axes is increased in order to convey the wafer solar cell. In the illustration, the thickness of the wafer solar cell in relation to the diameter of the cylinder-like contact elements 20, 10 and conveying elements 21, 11 is very much larger than in reality. The semiconductor wafers which are processed to form solar cells usually have thicknesses of less than 200 μm.

FIGS. 5 and 6 both show, diagrammatically and in a manner not true to scale, a side view of a pair of cylinder contact elements 10, 20 of a system according to a fourth embodiment during operation. The system shown in FIG. 5 corresponds to the system shown in FIGS. 3 and 4 with the difference that the upper contact element 10 or the upper contact elements 10 and the lower contact element 20 or the lower contact elements 20 are arranged opposite each other in pairs as viewed perpendicularly to the in-line transportation direction i. For this reason, a contact spacing between the upper contact element 10 and the opposite lower contact element 20 is realized by an electrically insulating spacing portion 100, 200. This spacing portion is arranged on the respective contact element 10, 20 axially adjacent to the contact periphery of the upper contact element 10 and/or axially adjacent to the lower contact element 20 as viewed along the rotation axis of the respective contact elements 10, 20. The upper contact element 10 and the lower contact element 20 are not conveying a wafer solar cell in FIG. 5, whereas they are conveying a wafer solar cell W in FIG. 6.

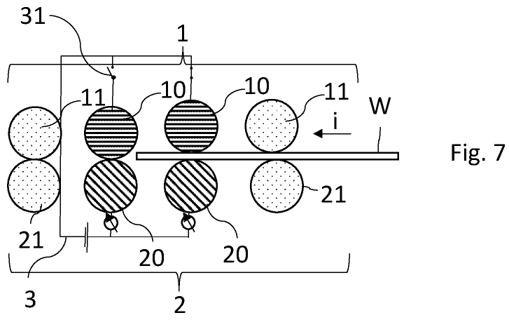

FIG. 7 shows a diagrammatic cross-sectional view, which is not true to scale, of a system according to a fifth embodiment during operation. The system shown in FIG. 7 corresponds to the system shown in FIGS. 3 and 4 with the difference that the upper contact elements 10 and the lower contact elements 20 are arranged opposite each other in pairs as viewed perpendicularly to the in-line transportation direction i and that the upper and lower conveying elements 11, 21 are arranged opposite each other in pairs as viewed perpendicularly to the in-line transportation direction i. Furthermore, the system, like the system from FIG. 1, has an electrical feed device 3 with the same functionality.

### LIST OF REFERENCE SIGNS

W Wafer solar cell
i In-line transportation direction
1 Upper contact device
10 Upper contact element
100 Spacing portion
11 Upper conveying element
2 Lower contact device
20 Lower contact element
200 Spacing portion
21 Lower conveying element
3 Electrical feed device
31 Switch
4 Laser device

1. A system for electrically contacting wafer solar cells having a front-face electrode and having a rear-face electrode, the system comprising:
an upper contact device for electrically contacting the front-face electrode of the wafer solar cell,
a lower contact device for electrically contacting the rear-face electrode of the wafer solar cell, and
an electrical voltage source to apply a defined voltage to the wafer solar cell and to regulate the flow of current between the upper contact device and the lower contact device,
wherein the upper contact device and the lower contact device are designed and configured to mechanically convey the wafer solar cell along an in-line transportation direction for an in-line production line for wafer solar cells during a contacting operation.

2. The system as claimed in claim 1, wherein the lower contact device moves equally as quickly as the wafer solar cell along the in-line transportation direction and is designed as a conveyor belt device.

3. The system as claimed in claim 2, wherein the upper contact device has at least one upper contact element as viewed along the in-line transportation direction and perpendicularly to the in-line transportation direction, the upper contact element being designed as a cylinder or as a roller with a contact periphery, wherein the contact periphery rolls on the front-face electrode of the wafer solar cell as quickly as the wafer solar cell moves along the in-line transportation direction.

4. The system as claimed in claim 1, wherein the upper contact device has at least one upper contact element as viewed along the in-line transportation direction and perpendicularly to the in-line transportation direction, the upper contact element being designed as a cylinder or as a roller with a contact periphery, wherein the contact periphery rolls on the front-face electrode of the wafer solar cell as quickly as the wafer solar cell moves along the in-line transportation direction, and the lower contact device has at least one lower contact element as viewed along the in-line transportation direction and perpendicularly to the in-line transportation direction, the lower contact element being designed as a cylinder or as a roller with a contact periphery, wherein the contact periphery rolls on the rear-face electrode of the wafer solar cell as quickly as the wafer solar cell moves along the in-line transportation direction.

5. The system as claimed in claim 4, wherein the upper contact element or the upper contact elements and the lower contact element or the lower contact elements are arranged opposite each other in pairs as viewed perpendicularly to the in-line transportation direction.

6. The system as claimed in claim 5, wherein the upper contact element and the opposite lower contact element, by way of their respective contact periphery, are arranged with a contact spacing from each other that is less than or equal to a thickness of the wafer solar cell.

7. The system as claimed in claim 6, wherein the contact spacing between the upper contact element and the opposite lower contact element is realized by an electrically insulating spacing portion which is arranged on the respective contact element axially adjacent to the contact periphery of the upper contact element and/or axially adjacent to the lower contact element as viewed along a rotation axis of the respective contact element.

8. The system as claimed in claim 4, wherein the lower contact device has a lower conveying element in the form of a roller or a cylinder with an electrically insulating contact periphery opposite the upper contact element as viewed perpendicularly to the in-line transportation direction and the upper contact device has an upper conveying element in the form of a roller or a cylinder with an electrically insulating contact periphery opposite the lower contact element.

9. The system as claimed in claim 8, wherein the upper contact device and the lower contact device have at least two upper contact elements and at least two lower contact elements as viewed along the in-line transportation direction, the spacing between the two upper contact elements and between the two lower contact elements along the in-line transportation direction being smaller than the dimensions of the wafer solar cell to be processed.

10. The system as claimed in claim 1, wherein the system has a laser device which moves or projects a laser beam over a front face of the wafer solar cell transversely to the in-line transportation direction.

11. An in-line production device for a wafer solar cell comprising a system as claimed in claim 1.

12. A method for producing a wafer solar cell using the system as claimed in claim 1, wherein an in-line transportation speed of the wafer solar cells along the in-line transportation direction of 0.1 to 60 m/min is realized.

13. A method for producing a wafer solar cell using the system as claimed in claim 1, wherein an in-line transportation speed of the wafer solar cells along the in-line transportation direction of 3 to 20 m/min is realized.

14. A method for producing a wafer solar cell using the system as claimed in claim 1, wherein an in-line transportation speed of the wafer solar cells along the in-line transportation direction of 6 to 20 m/min is realized.

15. A method for producing a wafer solar cell using the in-line production device as claimed in claim 11, wherein an in-line transportation speed of the wafer solar cells along the in-line transportation direction of 0.1 to 60 m/min is realized.

16. A method for producing a wafer solar cell using the in-line production device as claimed in claim 11, wherein an in-line transportation speed of the wafer solar cells along the in-line transportation direction of 3 to 20 m/min is realized.

17. A method for producing a wafer solar cell using the in-line production device as claimed in claim 11, wherein an in-line transportation speed of the wafer solar cells along the in-line transportation direction of 6 to 20 m/min is realized.
